(19) United States
(12) Patent Application Publication
(10) Pub. No.: US 2026/0371623 A1
(43) Pub. Date: Nov. 19, 2026

(54) CAPACITORS AND SEMICONDUCTOR DEVICES INCLUDING THE SAME

(71) Applicant: Samsung Electronics Co., Ltd., Suwon-si (KR)

(72) Inventors: Hojin Lee, Suwon-si (KR); Jinhong Kim, Suwon-si (KR); Beom Seok Kim, Suwon-si (KR); Sunghyun Kim, Suwon-si (KR); Jaeho Lee, Suwon-si (KR)

(73) Assignee: Samsung Electronics Co., Ltd., Suwon-si (KR)

(21) Appl. No.: 19/668,184

(22) Filed: May 5, 2026

(30) Foreign Application Priority Data
May 19, 2025 (KR) 10-2025-0064421

(51) Int. Cl. H10D 1/68; H10B 12/00; H10D 1/00

(52) U.S. Cl. CPC H10D 1/68; H10B 12/30; H10B 12/315; H10B 12/318; H10B 12/34; H10D 1/041; H10D 1/714; H10D 1/716

(57) ABSTRACT

The present disclosure may provide a capacitor. The capacitor includes a lower electrode, an upper electrode disposed to be spaced apart from the lower electrode, and a dielectric layer disposed between the lower electrode and the upper electrode, wherein the dielectric layer includes a first metal oxide region and a second metal oxide region disposed to be spaced apart from the first metal oxide region, the first metal oxide region includes an oxide of a tetravalent metal, and the second metal oxide region may include an oxide of a divalent metal.

### CROSS-REFERENCE TO RELATED APPLICATIONS

This present application claims priority to and the benefit under 35 U.S.C. § 119(a)-(d) of Korean Patent Application No. 10-2025-0064421, filed on May 19, 2025, in the Korean Intellectual Property Office, the entire disclosure of which is incorporated herein by reference.

### FIELD

The present disclosure relates to a capacitor and a semiconductor device including the same.

### BACKGROUND

As electronic devices are down-scaled, the space occupied by capacitors within the electronic devices is also being reduced. Accordingly, along with the reduction in the size of capacitors, a reduction in the thickness of the capacitor dielectric layer is also required. However, in such a case, a large leakage current may occur through the dielectric layer of the capacitor, which may make device operation difficult.

### SUMMARY

An object of the present disclosure is to provide a capacitor with a low leakage current value and a semiconductor device including the same.

According to some embodiments of the present disclosure for solving the technical problem, a capacitor includes a lower electrode, an upper electrode disposed to be spaced apart from the lower electrode, and a dielectric layer disposed between the lower electrode and the upper electrode, wherein the dielectric layer includes a first metal oxide region and a second metal oxide region disposed to be spaced apart from the first metal oxide region, the first metal oxide region includes an oxide of a tetravalent metal, and the second metal oxide region may include an oxide of a divalent metal.

According to some embodiments of the present disclosure for solving the technical problem, a capacitor includes a lower electrode, an upper electrode disposed to be spaced apart from the lower electrode, a dielectric layer disposed between the lower electrode and the upper electrode, a lower interface film disposed between the lower electrode and the dielectric layer, and an upper interface film disposed between the upper electrode and the dielectric layer, wherein the dielectric layer includes a first metal oxide region and a second metal oxide region disposed to be spaced apart from the first metal oxide region, each of the first metal oxide region and the second metal oxide region is a region distributed in a doped form within the dielectric layer or a layer-shaped region formed within the dielectric layer, the first metal oxide region includes PbO₂, SnO₂, GeO₂, or any combination thereof and has a rutile-type crystal structure, the second metal oxide region includes BaO, SrO, CaO, MgO, ZnO, CdO, BeO, or any combination thereof, and the first metal oxide region locates closer to the lower electrode than the second metal oxide region.

According to some embodiments of the present disclosure for solving the technical problem, a semiconductor device includes a transistor disposed on a substrate, and a capacitor electrically connected to the transistor, wherein the capacitor includes a lower electrode, an upper electrode disposed to be spaced apart from the lower electrode, and a dielectric layer disposed between the lower electrode and the upper electrode, wherein the dielectric layer includes a first metal oxide region and a second metal oxide region disposed to be spaced apart from the first metal oxide region, the first metal oxide region includes an oxide of a tetravalent metal, and the second metal oxide region includes an oxide of a divalent metal.

According to some embodiments of the present disclosure for solving the technical problem, a method for manufacturing a capacitor may include forming a lower electrode, forming a dielectric layer including a first metal oxide region and a second metal oxide region disposed to be spaced apart from the first metal oxide region on the lower electrode, and forming an upper electrode on the dielectric layer, wherein the first metal oxide region includes an oxide of a tetravalent metal, and the second metal oxide region may include an oxide of a divalent metal.

According to some embodiments, forming the dielectric layer including the first metal oxide region and the second metal oxide region disposed to be spaced apart from the first metal oxide region on the lower electrode may include forming a dielectric layer having a rutile-type crystal structure by epitaxy growth on the lower electrode, forming the first metal oxide region by an atomic layer deposition process using a precursor on the dielectric layer, forming a dielectric layer by an atomic layer deposition process using a precursor on the first metal oxide region, forming the second metal oxide region by an atomic layer deposition process using a precursor on the dielectric layer, and forming a dielectric layer by an atomic layer deposition process using a precursor on the second metal oxide region, and the steps may be performed under a temperature condition of 200° C.-400° C.

According to some embodiments, the first metal oxide region may include lead oxide (PbO₂), tin oxide (SnO₂), germanium oxide (GeO₂), or any combination thereof.

According to some embodiments, the method for manufacturing a capacitor may further include forming a lower interface film on the lower electrode.

According to some embodiments, the first metal oxide region may be a layer-shaped region formed within the dielectric layer or a region where an oxide of a tetravalent metal is distributed in a doped form within the dielectric layer.

According to some embodiments, the second metal oxide region may include BaO, SrO, CaO, MgO, ZnO, CdO, BeO or any combination thereof.

According to some embodiments, the method for manufacturing a capacitor may further include forming an upper interface film on the dielectric layer.

According to some embodiments, the second metal oxide region may be a layer-shaped region formed within the dielectric layer or a region where an oxide of a divalent metal is distributed in a doped form within the dielectric layer.

According to some embodiments, when measured from the lower electrode, the first metal oxide region is located in a region between 10%-40% of the thickness of the dielectric layer, and when measured from the lower electrode, the second metal oxide region may be located in a region between 40%-100% of the thickness of the dielectric layer.

According to some embodiments, the thickness of the first metal oxide region may be greater than the thickness of the second metal oxide region.

According to some embodiments of the present disclosure, it is possible to provide a capacitor with improved characteristics for blocking leakage current and a semiconductor device including the same.

### BRIEF DESCRIPTION OF THE DRAWINGS

FIGS. 1-3 are schematic diagrams for explaining a capacitor according to some embodiments of the present disclosure.

FIG. 4 is a graph showing leakage current according to capacitance for the capacitors manufactured in Embodiment 1 and Comparative Example 1.

FIG. 5 is a graph showing leakage current according to applied voltage for the capacitors manufactured in Embodiment 1 and Comparative Example 1.

FIG. 6 is a graph showing leakage current according to equivalent oxide thickness (EOT) for the capacitors manufactured in Embodiment 1 and Comparative Example 1.

FIG. 7 is a schematic diagram for explaining a capacitor according to some embodiments of the present disclosure.

FIG. 8 is a schematic diagram for explaining a semiconductor device according to some embodiments of the present disclosure.

FIG. 9 is a schematic diagram for explaining a semiconductor device according to some embodiments of the present disclosure.

FIG. 10 is a cross-sectional view taken along line A-A of FIG. 9.

FIG. 11 is a diagram for explaining a capacitor according to some embodiments of the present disclosure.

FIG. 12 is a diagram for explaining a semiconductor device according to some embodiments of the present disclosure.

FIG. 13 is a cross-sectional view taken along line B-B of FIG. 12.

FIG. 14 is a diagram for explaining a semiconductor device according to some embodiments of the present disclosure.

FIG. 15 is a cross-sectional view taken along line C-C of FIG. 14.

FIG. 16 and FIG. 17 are flowcharts illustrating a method of manufacturing a capacitor according to some embodiments of the present disclosure.

### DETAILED DESCRIPTION

Hereinafter, a capacitor and a semiconductor device including the same according to some embodiments of the present disclosure will be described in detail with reference to the drawings.

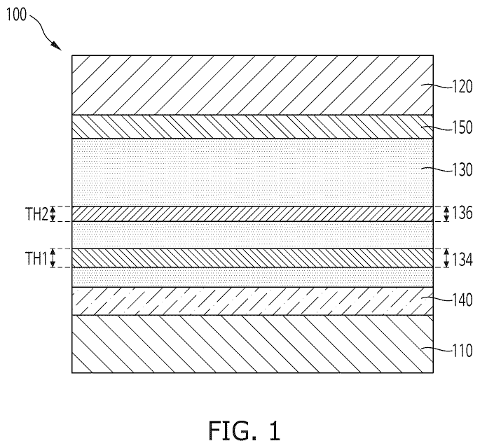

FIGS. 1-3 are schematic diagrams for explaining a capacitor according to some embodiments of the present disclosure.

Referring to FIG. 1, a capacitor 100 may include a lower electrode 110, an upper electrode 120 disposed to be spaced apart from the lower electrode 110, and a dielectric layer 130 disposed between the lower electrode 110 and the upper electrode 120. The capacitor 100 may further include a lower interface film 140 disposed between the lower electrode 110 and the dielectric layer 130 and/or an upper interface film 150 disposed between the upper electrode 120 and the dielectric layer 130. The capacitor 100 may be, for example, a capacitor.

The lower electrode 110 may be disposed on a substrate. The substrate may be a part of a structure that supports the capacitor, or a part of a device connected to the capacitor. The substrate may include a semiconductor material pattern, an insulating material pattern, and/or a conductive material pattern. In addition, the substrate may, for example, include a semiconductor material such as silicon (Si), germanium (Ge), silicon germanium (SiGe), silicon carbide (SiC), gallium arsenide (GaAs), indium arsenide (InAs), indiumphosphide (InP), etc., and/or may also include an insulating material such as silicon oxide, silicon nitride, or silicon oxynitride.

The upper electrode 120 may be disposed to be spaced apart from and face the lower electrode 110. The lower electrode 110 and/or the upper electrode 120 may each independently include a metal, a metal nitride, a metal oxide, or a combination thereof. Specifically, the lower electrode 110 and/or the upper electrode 120 may each independently include a metal such as platinum (Pt), iridium (Ir), ruthenium (Ru), molybdenum (Mo), vanadium (V), etc., a conductive metal nitride such as titanium nitride (TiN), niobium nitride (NbN), titanium silicon nitride (TiSiN), molybdenum nitride (MoN), vanadium nitride (VN), scandium nitride (ScN) or any combination thereof, and/or a conductive metal oxide such as platinum oxide (PtO), iridium oxide (IrO₂), ruthenium oxide (RuO₂), strontium ruthenium oxide (SrRuO₃), barium strontium ruthenium oxide ((Ba, Sr)RuO₃), calcium ruthenium oxide (CaRuO₃), lanthanum strontium cobalt oxide ((La, Sr)CoO₃).

For example, the lower electrode 110 and/or the upper electrode 120 may each independently include a metal nitride represented as MM′N. Here, M is a metal element, M′ is an element different from M, and N is nitrogen. This metal nitride may also include an MN metal nitride doped with element M′. M may be one or more elements selected from Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, and U. M′ may be one or more elements selected from H, Li, Be, B, N, O, Na, Mg, Al, Si, P, S, K, Ca, Sc, Ti, V, Cr, Mn, Fe, Co, Ni, Cu, Zn, Ga, Ge, As, Se, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, and U. When the compositional ratio of M, M′, and N in the metal nitride MM′N is denoted as x:y:z, it may be that 0≤x≤2, 0≤y≤2, and 0<z≤4, and one of x and y is not 0.

The lower electrode 110 and/or the upper electrode 120 may each independently be a single material layer or a stacked structure of a plurality of material layers. For example, the lower electrode 110 and/or the upper electrode 120 may each independently be a single layer of titanium nitride (TiN), or a single layer of niobium nitride (NbN). Alternatively, the lower electrode 110 and/or the upper electrode 120 may have a stacked structure including a first electrode layer including titanium nitride (TiN) and a second electrode layer including niobium nitride (NbN).

The dielectric layer 130 may include a high-k dielectric film. The term “high-k dielectric film” as used in the present specification may mean a dielectric film having a higher dielectric constant than a silicon oxide film. The dielectric layer 130 may comprise a metal oxide including at least one metal selected from Zr, Hf, Ti, Al, Ce, Y, Mg, Sc, Ga, In, and Si. The dielectric layer 130 may have a multi-film structure including a plurality of high-k dielectric films sequentially stacked on the lower electrode 110. Specifically, the dielectric layer 130 may include zirconium oxide (ZrO₂), hafnium oxide (HfO₂), zirconium-hafnium oxide (ZrHfO), titanium oxide (TiO₂), aluminum oxide (Al₂O₃), germanium oxide (GeO₂), yttrium oxide (Y₂O₃), magnesium oxide (MgO), scandium oxide (Sc₂O₃), gallium oxide (Ga₂O₃), indium oxide (In₂O₃), silicon oxide (SiO₂), or any combination thereof, but is not limited thereto.

At least a part of the dielectric layer 130 may be an epitaxial layer. The dielectric layer 130 may be formed by, for example, epitaxy growth. Accordingly, the dielectric layer 130 may have the same or similar crystal structure, the same or similar lattice constant, etc. as the lower electrode 110 or the lower interface film 140. A part or all of the dielectric layer 130 may include an epitaxial region.

The dielectric layer 130 may have a rutile phase crystal structure. For example, the dielectric layer 130 may include TiO₂ in a rutile phase. TiO₂ has a difference in dielectric constant depending on the phase. While TiO₂ in an anatase phase exhibits a dielectric constant of about 40, TiO₂ in a rutile phase may exhibit a large dielectric constant value ranging from approximately 80 to 170 depending on the growth direction. Therefore, the dielectric layer 130 including TiO₂ may have a dielectric constant of greater than or equal to about 80 and less than or equal to about 170. The dielectric layer 130 may be grown with a rutile-type crystal structure on the lower electrode 110 or the lower interface film 140.

The dielectric layer 130 may be formed through deposition methods such as Atomic Layer Deposition (ALD), Chemical Vapor Deposition (CVD), Physical Vapor Deposition (PVD), or sputtering. Among these, the atomic layer deposition (ALD) method has the advantage that it can form a uniform layer in atomic units and can be performed at a relatively low temperature. The process temperature of the atomic layer deposition (ALD) method may be appropriately adjusted according to the thermal stability of the metal precursor and/or oxidant, and may be greater than or equal to 100° C. and less than or equal to 700° C.

Atomic layer deposition (ALD) may supply the source gases for film formation not simultaneously but in a time-divided manner in the form of independent pulses. Such ALD may interpose a purge step with an inert gas between the supplies of the source gases to remove remaining gases or by-products that have not reacted (or chemically adsorbed). For the purge step, an inert gas such as Ar, He, Ne and/or N₂ gas may be used.

For example, when a precursor is supplied to a reactor and then the reactor is purged by supplying an inert gas (purge gas), a thin layer of the chemically adsorbed precursor may remain on the substrate surface at a monolayer level, and all the remaining precursor may exit the reactor. Thereafter, when an oxidant is supplied, it may react with the precursor on the substrate surface to form a desired dielectric layer thinly (for example, as a monolayer). Thereafter, a purge step may be performed to remove the physically adsorbed oxidant or by-products in the reactor. The process consisting of precursor supply→purge→oxidant supply→purge is called one cycle of a general ALD process, and a film may be formed to a desired thickness by controlling the number of cycles. As the precursor for the dielectric layer 130, a Ti-containing precursor may be used. For example, the Ti-containing precursor may include a Ti-containing alkoxide (for example, Ti-tetra-isopropoxide (TTIP), Ti(CpMe₅) (OMe)₃ (pentamethyl cyclopentadienyl titanium trimethoxide), etc.), a Ti-containing amine (for example, TDMAT(tetra-kis(dimethylamino)titanium), etc.), a Ti-containing halide (for example, TiCl₄, TiI₄, etc.), or a combination thereof. As the oxidant, O₃, N₂O and/or plasma may be used.

The dielectric layer 130 may include a first metal oxide region 134 and a second metal oxide region 136 disposed to be spaced apart from the first metal oxide region 134. The second metal oxide region 136 may be disposed to be spaced apart from and face the first metal oxide region 134. The first metal oxide region 134 and the second metal oxide region 136 may be disposed along the thickness direction of the dielectric layer 130. The boundary between the dielectric layer 130, the first metal oxide region 134, and the second metal oxide region 136 may be unclear. Specifically, the boundary between the dielectric layer 130 and the first metal oxide region 134 and the boundary between the dielectric layer 130 and the second metal oxide region 136 may be unclear. For example, when the dielectric layer 130, the first metal oxide region 134, and the second metal oxide region 136 are manufactured with a similar composition or have a small thickness, the boundary with an adjacent layer may not be clearly distinguished due to material diffusion between them.

The first metal oxide region 134 may include an oxide of a tetravalent metal. Specifically, the first metal oxide region 134 may include lead oxide (PbO₂), tin oxide (SnO₂), germanium oxide (GeO₂), or any combination thereof.

The first metal oxide region 134 may have a rutile-type crystal structure. The first metal oxide region 134 may be formed in a doped form within the dielectric layer 130 having a rutile-type crystal structure. The first metal oxide region 134 may be formed in a doped form within the crystal lattice of the dielectric layer 130. Specifically, the first metal oxide region 134 may have the form of ion substitution at the metal ion sites constituting the dielectric layer 130, and may be formed dispersed within the dielectric layer 130. In this case, because the first metal oxide region 134 has the same rutile-type crystal structure as the dielectric layer 130, it may contribute to the crystal phase stabilization of the dielectric layer 130.

The first metal oxide region 134 may be deposited by an atomic layer deposition process. The description of the atomic layer deposition process for the first metal oxide region 134 may be the same as the description of the atomic layer deposition process for the dielectric layer 130, and thus a duplicate description is omitted. The first metal oxide region 134 may be deposited by a general ALD process, which is a process consisting of precursor supply→purge→oxidant supply→purge, or an ACALD(Atomic Layer Co-Deposition) process, which is a process consisting of first precursor supply→purge→second precursor supply→purge→oxidant supply→purge. In the general ALD process, a Ge-containing precursor may be used as the precursor for the first metal oxide region 134. In the ACALD process, a Ti-containing precursor may be used as the first precursor. In the ACALD process, a Ge-containing precursor may be used as the second precursor. For example, the Ge-containing precursor may include Ge(OnBu)₄, Ge(NMe₂)₄, GeCl₄, or any combination thereof.

When the first metal oxide region 134 is formed by a general ALD process, the first metal oxide region 134 may be a layer-shaped region formed within the dielectric layer 130. When the first metal oxide region 134 is formed by an ACALD process, the first metal oxide region 134 may be a region where an oxide of a tetravalent metal is distributed in a doped form within the dielectric layer 130.

The first metal oxide region 134 may be located closer to the lower electrode 110 than the second metal oxide region 136. For example, when measured from the lower electrode 110, the first metal oxide region 134 may be located in a region between 10% and 40% of the thickness of the dielectric layer 130. When measured from the lower electrode 110, the second metal oxide region 136 may be located in a region between 40% and 100% of the thickness of the dielectric layer 130.

In a general ALD process or an ACALD process, the number of cycles for forming the first metal oxide region 134 may be greater than the number of cycles for forming the second metal oxide region 136. Accordingly, the thickness TH1 of the first metal oxide region 134 may be greater than the thickness TH2 of the second metal oxide region 136. However, it is not limited thereto, and the thickness TH1 of the first metal oxide region 134 may be less than or equal to the thickness TH2 of the second metal oxide region 136.

The second metal oxide region 136 may include an oxide of a divalent metal. Specifically, the second metal oxide region 136 may include BaO, SrO, CaO, MgO, ZnO, CdO, BeO, or any combination thereof. The oxide of a divalent metal has excellent oxygen diffusivity and may promote oxygen movement within the dielectric layer 130. Accordingly, the tetravalent metal oxide included in the dielectric layer 130 can be more smoothly supplied with the oxygen necessary to capture or stabilize oxygen vacancies 197.

The second metal oxide region 136 may be deposited by an atomic layer deposition process. The description of the atomic layer deposition process for the second metal oxide region 136 may be the same as the description of the atomic layer deposition process for the dielectric layer 130, and thus a duplicate description is omitted. The second metal oxide region 136 may be deposited by a general ALD process, which is a process consisting of precursor supply→purge→oxidant supply→purge, or an ACALD (Atomic Layer Co-Deposition) process, which is a process consisting of first precursor supply→purge→second precursor supply→purge→oxidant supply→purge. In a general ALD process, an Mg-containing precursor may be used as the precursor for the second metal oxide region 136. In an ACALD process, a Ti-containing precursor may be used as the first precursor. In an ACALD process, an Mg-containing precursor may be used as the second precursor. For example, the Mg-containing precursor may include MgCp₂ (Mg(C₅H₅)₂), Mg(EtCp)₂ (Mg(C₅H₄C₂H₅)₂), or any combination thereof.

When the second metal oxide region 136 is formed by a general ALD process, the second metal oxide region 136 may be a layer-shaped region formed within the dielectric layer 130. When the second metal oxide region 136 is formed by an ACALD process, the second metal oxide region 136 may be a region where an oxide of a divalent metal is distributed in a doped form within the dielectric layer 130. The second metal oxide region 136 may be formed in a doped form within the crystal lattice of the dielectric layer 130. Specifically, the second metal oxide region 136 may have a form of ion substitution at the metal ion sites constituting the dielectric layer 130 and may be formed dispersed within the dielectric layer 130.

Heat treatment may also be performed on the dielectric layer 130 or the metal oxide regions 134, 136. Specifically, heat treatment may be performed after forming the dielectric layer 130 and/or the upper electrode 120. As another example, heat treatment may be performed after the first metal oxide region 134 and/or the second metal oxide region 136 are formed. During the heat treatment process, metal elements in the dielectric layer 130 may undergo material diffusion, and some or all of the metal oxides in the dielectric layer 130 or the metal oxide regions 134, 136 may be crystallized, or the size of the crystal grains may increase.

The heat treatment may be performed at a temperature from 400° C. to 1100° C., but is not limited thereto. The heat treatment may be performed for a time of 1 nano-second or more, 1 micro-second or more, 0.001 seconds or more, 0.01 seconds or more, 0.05 seconds or more, 0.1 seconds or more, 0.5 seconds or more, 1 second or more, 3 seconds or more, 5 seconds or more, 10 minutes or less, 5 minutes or less, 1 minute or less, or 30 seconds or less, but is not limited thereto.

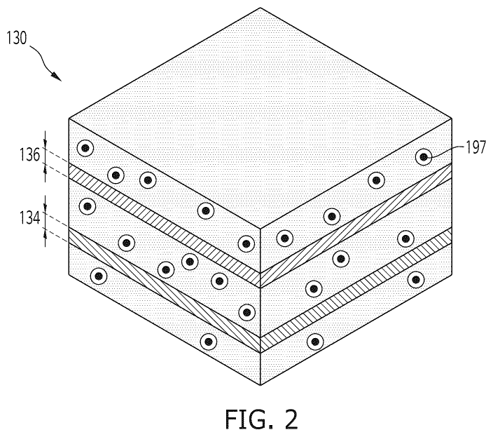

As shown in FIG. 2, as oxygen included in the dielectric layer 130 is desorbed due to the influence of heat or an electric field, oxygen vacancies 197 may be generated. The oxygen vacancies 197 increase trap sites within the dielectric layer 130, and if charges tunnel through the traps, a leakage current may be generated. In addition, the presence of the oxygen vacancies 197 may deteriorate the dielectric properties of the dielectric layer 130 and may cause a decrease in capacitance. Furthermore, the oxygen vacancies 197 increase the instability of the crystal lattice, thereby hindering crystallization and may raise the crystallization temperature of the dielectric layer 130.

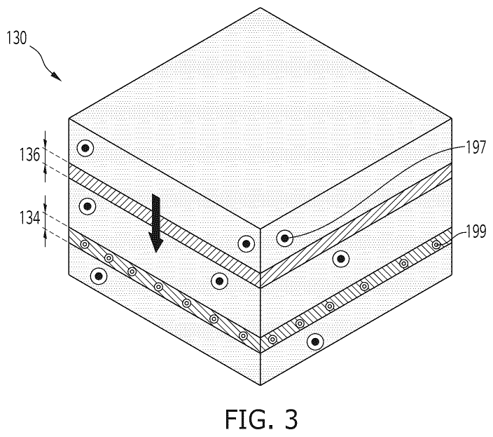

As shown in FIG. 3, by including the first metal oxide region 134 in the dielectric layer 130, the generation of oxygen vacancies 197 in the dielectric layer 130 can be suppressed. In addition, the first metal oxide region 134 may supply oxygen to the dielectric layer 130 to reduce the oxygen vacancies 197. That is, captured oxygen vacancies 199 may be formed by the tetravalent metal oxide of the first metal oxide region 134. By capturing the oxygen vacancies 197 by the first metal oxide region 134, the captured oxygen vacancies 199 may be stabilized within the crystal, and their mobility and electrical activity may be lowered. The first metal oxide region 134 may prevent the deterioration of the dielectric properties of the dielectric layer 130. In addition, the first metal oxide region 134 may prevent the capacitance of the dielectric layer 130 from being lowered. Furthermore, the first metal oxide region 134 may lower the crystallization temperature of the dielectric layer 130.

The lower interface film 140 may act as a barrier layer that prevents impurity diffusion and/or movement between the lower electrode 110 and the dielectric layer 130. For example, the lower interface film 140 may prevent some atoms included in the lower electrode 110 from penetrating into the dielectric layer 130, and may prevent some atoms included in the dielectric layer 130 from diffusing to the lower electrode 110. The lower interface film 140 may include a transition metal oxide having electrical conductivity. Specifically, the lower interface film 140 may include an oxide of a metal included in the lower electrode 110. For example, the lower interface film 140 may include TiO₂, Nb₂O₃, MoO₂, RuO₂, IrO₂, VO₂, Sc₂O₃, Ta₂O₅, SnO₂, or any combination thereof.

The upper interface film 150 may act as a barrier layer that prevents impurity diffusion and/or movement between the upper electrode 120 and the dielectric layer 130. For example, the upper interface film 150 may prevent some atoms included in the upper electrode 120 from penetrating into the dielectric layer 130, and may prevent some atoms included in the dielectric layer 130 from diffusing to the upper electrode 120. The upper interface film 150 may include a transition metal oxide having electrical conductivity. Specifically, the upper interface film 150 may include an oxide of a metal included in the upper electrode 120. For example, the upper interface film 150 may include TiO₂, Nb₂O₃, MoO₂, RuO₂, IrO₂, VO₂, Sc₂O₃, Ta₂O₅, SnO₂, or any combination thereof.

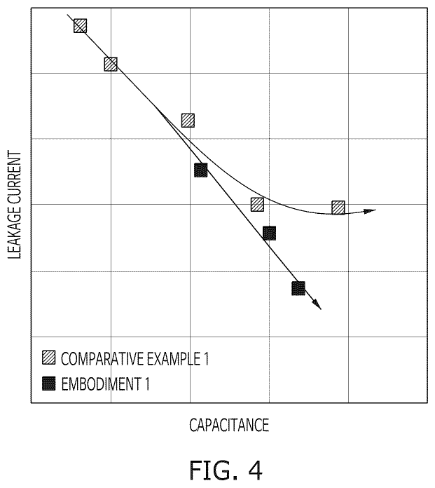

FIG. 4 is a graph showing leakage current according to capacitance for the capacitors manufactured in Embodiment 1 and Comparative Example 1.

Referring to FIG. 4, the capacitor according to Embodiment 1 may include a lower electrode, a lower interface film, a dielectric layer having a rutile-type crystal structure and having two metal oxide regions each including an oxide of a divalent metal and an oxide of a tetravalent metal, and an upper electrode. The capacitor according to Comparative Example 1 may include a lower electrode, a lower interface film, a dielectric layer having a rutile-type crystal structure and having a metal oxide region including an oxide of a divalent metal, and an upper electrode. FIG. 4 shows the difference in leakage current characteristics depending on the presence or absence of the first metal oxide region in Embodiment 1 and Comparative Example 1. Comparative Example 1 does not include the first metal oxide region of the present invention (for example, a region having an oxide of a tetravalent metal).

FIG. 4 illustrates the correlation between the leakage current measured under an applied voltage of 1.0 V and the capacitance at 0 V. In the case of Comparative Example 1, as the concentration of MgO increases, the leakage current decreases, but after a certain section, the decrease in leakage current shows a negligible trend. However, in Embodiment 1, as the concentration of MgO increases, it can be confirmed that a lower leakage current value is secured under the same capacitance condition. Therefore, it can be confirmed that Embodiment 1 has excellent leakage current characteristics.

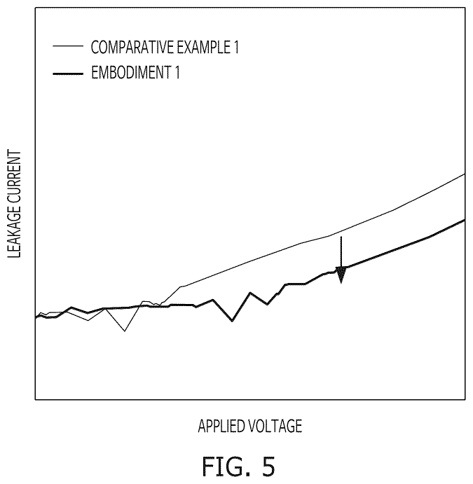

FIG. 5 is a graph showing leakage current according to applied voltage for the capacitors manufactured in Embodiment 1 and Comparative Example 1.

Referring to FIG. 5, the capacitor according to Embodiment 1 may include a lower electrode, a lower interface film, a dielectric layer having a rutile-type crystal structure and having two metal oxide regions each including an oxide of a divalent metal and an oxide of a tetravalent metal, and an upper electrode. The capacitor according to Comparative Example 1 may include a lower electrode, a lower interface film, a dielectric layer having a rutile-type crystal structure and having a metal oxide region including an oxide of a divalent metal, and an upper electrode. FIG. 5 shows the difference in leakage current characteristics depending on the presence or absence of the first metal oxide region in Embodiment 1 and Comparative Example 1. Comparative Example 1 does not include the first metal oxide region of the present invention (for example, a region having an oxide of a tetravalent metal).

FIG. 5 illustrates the change in leakage current according to the applied voltage. Embodiment 1 shows a lower or similar leakage current value than Comparative Example 1 over the entire voltage range, and it can be confirmed that it has excellent leakage current characteristics, especially in the high voltage section.

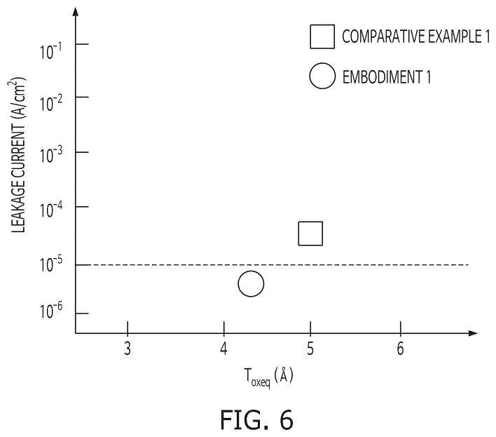

FIG. 6 is a graph showing leakage current according to equivalent oxide thickness (EOT) for the capacitors manufactured in Embodiment 1 and Comparative Example 1.

Referring to FIG. 6, the capacitor according to Embodiment 1 may include a lower electrode, a lower interface film, a dielectric layer having a rutile-type crystal structure and having two metal oxide regions each including an oxide of a divalent metal and an oxide of a tetravalent metal, and an upper electrode. The capacitor according to Comparative Example 1 may include a lower electrode, a lower interface film, a dielectric layer having a rutile-type crystal structure and having a metal oxide region including an oxide of a divalent metal, and an upper electrode. FIG. 6 shows the difference in leakage current characteristics depending on the presence or absence of the first metal oxide region in Embodiment 1 and Comparative Example 1, which does not include the first metal oxide region of the present invention (for example, a region having an oxide of a tetravalent metal).

In FIG. 6, the thickness of the dielectric layer is shown as the Equivalent Oxide Thickness (EOT). The leakage current may be the current density when a voltage of 1.0 V is applied to the capacitor. Embodiment 1 may exhibit a leakage current value of 10⁻⁵ A/cm² or less. Therefore, it can be confirmed that Embodiment 1 has excellent leakage current characteristics. In addition, it can be confirmed that Embodiment 1 has better crystallinity than Comparative Example 1.

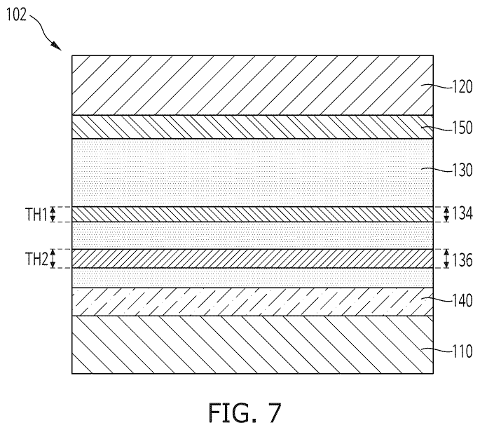

FIG. 7 is a schematic diagram for explaining a capacitor according to some embodiments of the present disclosure. For convenience of explanation, the description will focus on configurations different from those described in FIG. 1 to FIG. 3.

Referring to FIG. 7, in a capacitor according to some embodiments, the thickness TH1 of the first metal oxide region 134 may be smaller than the thickness TH2 of the second metal oxide region 136. In addition, the first metal oxide region 134 may be located farther from the lower electrode 110 than the second metal oxide region 136.

For example, when measured from the lower electrode 110, the first metal oxide region 134 may be located in a region between 40% and 100% of the thickness of the dielectric layer 130. When measured from the lower electrode 110, the second metal oxide region 136 may be located in a region between 10% and 40% of the thickness of the dielectric layer 130.

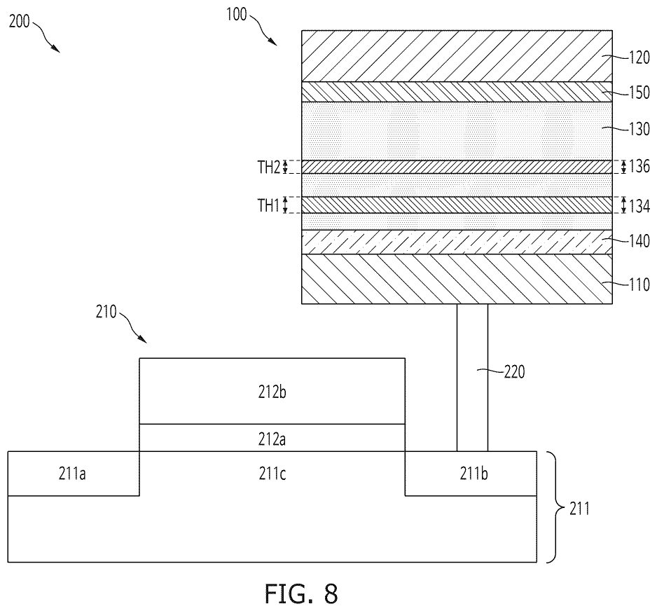

FIG. 8 is a schematic diagram for explaining a semiconductor device according to some embodiments of the present disclosure.

Referring to FIG. 8, a schematic diagram showing a semiconductor device (a connection structure of a capacitor and a transistor) according to some embodiments is shown. Referring to FIG. 8, a semiconductor device 200 may have a structure in which a capacitor 100 (for example, a capacitor), including the dielectric layer 130 including the aforementioned first metal oxide region 134 and second metal oxide region 136, and a transistor 210 are electrically connected by a contact 220. For example, one of the electrodes 110, 120 of the capacitor 100 and one of the source region and drain region 211a, 211b formed on the semiconductor substrate 211 of the transistor 210 may be electrically connected by the contact 220. FIG. 8 shows an example of a semiconductor device 200 including the capacitor 100 of FIG. 1, but the capacitor 102 of FIG. 7 may also be included in the semiconductor device 200.

The transistor 210 may include a semiconductor substrate 211 including a source region and a drain region 211a, 211b and a channel region 211c located between the source region and the drain region, and a gate structure disposed on the semiconductor substrate 211 to face the channel region 211c and including a gate insulating layer 212a and a gate electrode 212b.

The semiconductor substrate 211 may include a semiconductor material. The semiconductor substrate 211 may, for example, include a semiconductor material such as silicon (Si), germanium (Ge), silicon germanium (SiGe), silicon carbide (SiC), gallium arsenide (GaAs), indium arsenide (InAs), indium phosphide (InP), etc., and may be used in various modified forms such as silicon on insulator (SOI).

The semiconductor substrate 211 may include a source region 211a, a drain region 211b, and a channel 211c electrically connected to the source region 211a and the drain region 211b. The source region 211a may be electrically connected or in contact with one end of the channel 211c, and the drain region 211b may be electrically connected or in contact with the other end of the channel 211c. In other words, the channel 211c may be defined as a region between the source region 211a and the drain region 211b in the semiconductor substrate 211.

The source region 211a, the drain region 211b, and the channel 211c may each be independently formed by implanting impurities into different regions of the semiconductor substrate 211, and in this case, the source region 211a, the channel 211c, and the drain region 211b may include the semiconductor substrate material as a base material. In addition, the source region 211a and the drain region 211b may be formed of a conductive material, and for example, may each independently include a metal, a metal compound, or a conductive polymer.

The channel 211c may also be implemented as a separate material layer (thin film). In this case, for example, the channel 211c may include not only semiconductor materials such as Si, Ge, SiGe, III-V group, etc., but also an oxide semiconductor, a nitride semiconductor, an oxynitride semiconductor, a two-dimensional material (2D material), a quantum dot, and/or an organic semiconductor. For example, the oxide semiconductor may include InGaZnO, etc., the two-dimensional material may include a transition metal dichalcogenide (TMD) or graphene, and the quantum dot may include a colloidal quantum dot (colloidal QD) or a nanocrystal structure.

The gate electrode 212b may be disposed on the semiconductor substrate 211 to be spaced apart from the semiconductor substrate 211 and to face the channel 211c. The gate electrode 212b may have a conductivity of 1 Mohm/square or less. The gate electrode 212b may include a metal, a metal nitride, a metal carbide, and/or polysilicon. For example, the metal may include aluminum (Al), tungsten (W), molybdenum (Mo), titanium (Ti), and/or tantalum (Ta), and the metal nitride film may include a titanium nitride film (TiN film) and/or a tantalum nitride film (TaN film). The metal carbide may be a metal carbide doped with (or containing) aluminum and/or silicon, and specific examples may include TiAlC, TaAlC, TiSiC, or TaSiC. The gate electrode 212b may also have a structure in which a plurality of materials are stacked, for example, it may have a stacked structure of a metal nitride layer/metal layer such as TiN/Al, or a stacked structure of a metal nitride layer/metal carbide layer/metal layer such as TiN/TiAlC/W. The gate electrode 212b may include titanium nitride (TiN) or molybdenum (Mo), and the above examples may be used in various modified forms.

The gate insulating layer 212a may include silicon oxide, silicon nitride, aluminum oxide, hafnium oxide, zirconium oxide, etc., or may include a 2D insulator such as h-BN (hexagonal boron nitride). For example,

The gate insulating layer 212a may include silicon oxide (SiO₂), silicon nitride (SiNx), etc., and may also include hafnium oxide (HfO₂), hafnium silicon oxide (HfSiO₄), lanthanum oxide (La₂O₃), lanthanum aluminum oxide (LaAlO₃), zirconium oxide (ZrO₂), hafnium zirconium oxide (HfZrO₂), zirconium silicon oxide (ZrSiO₄), tantalum oxide (Ta₂O₅), titanium oxide (TiO₂), strontium titanium oxide (SrTiO₃), yttrium oxide (Y₂O₃), aluminum oxide (Al₂O₃), lead scandium tantalum oxide (PbSc_{0.5}Ta_{0.5}O₃), lead zinc niobate (PbZnNbO₃), etc. In addition, the gate insulating layer 212a may include a metal oxynitride such as aluminum oxynitride (AlON), zirconium oxynitride (ZrON), hafnium oxynitride (HfON), lanthanum oxynitride (LaON), yttrium oxynitride (YON), etc., a silicate such as ZrSiON, HfSiON, YSiON, LaSiON, etc., or an aluminate such as ZrAlON, HfAlON, etc. In addition, the gate insulating layer 212a may include the aforementioned dielectric layer 130. The gate insulating layer 212a may form a gate structure together with the gate electrode 212b.

The contact 220 may include a conductive material, for example, tungsten, copper, aluminum, polysilicon, etc.

The arrangement of the capacitor 100 and the transistor 210 can be variously modified. For example, the capacitor 100 may be disposed on the semiconductor substrate 211, or may have a structure embedded in the semiconductor substrate 211.

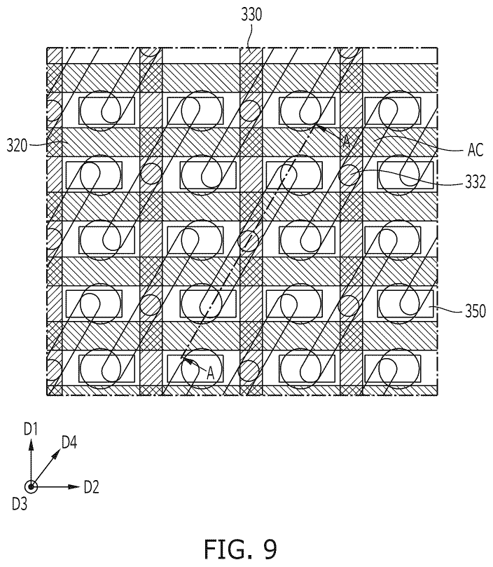

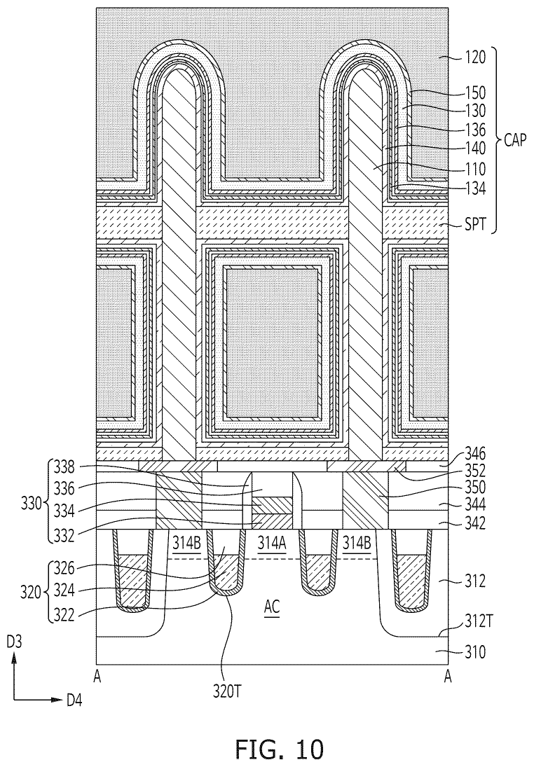

FIG. 9 is a schematic diagram for explaining a semiconductor device according to some embodiments of the present disclosure. FIG. 10 is a cross-sectional view taken along line A-A of FIG. 9.

Referring to FIG. 9 and FIG. 10, a semiconductor device according to some embodiments may include a structure in which a plurality of capacitors and a plurality of transistors are repeatedly arranged. The semiconductor device may include a substrate 310, an active pattern AC located on the substrate 310, a gate structure 320 overlapping with the active pattern AC, a bit line BL connected to the active pattern AC on one side of the gate structure 320, a contact 350 connected to the active pattern AC on the other side of the gate structure 320, and a capacitor CAP connected to the contact 350.

The substrate 310 may include a conductive region, for example, a well doped with impurities or a structure doped with impurities.

A device isolation film 312 may have a shallow trench isolation (STI) structure. For example, the device isolation film 312 may include an insulating material filling a device isolation trench 312T formed in the substrate 310. The insulating material may include fluoro-silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), or tonen silazene (TOSZ), but is not limited thereto and may be variously changed. The active pattern AC may be defined by the device isolation film 312. The active pattern AC may be disposed on the substrate 310.

The active pattern AC may have a bar shape having a minor axis and a major axis, respectively, in a plan view. As shown in FIG. 9, the major axis of the active pattern AC may be arranged along a diagonal direction D4 parallel to the upper surface of the substrate 310. P-type or N-type impurities may be doped into the active pattern AC.

A gate line trench 320T may intersect with the active pattern ac and be formed to a predetermined depth from the upper surface of the substrate 310 toward a third direction (D3 direction), which is a vertical direction. A portion of the gate line trench 320T may extend into the device isolation film 312, and the portion of the gate line trench 320T formed in the device isolation film 312 may have a bottom surface located at a lower level than the portion of the gate line trench 320T formed in the active pattern AC.

In an upper region of the active pattern AC located on both sides of the gate line trench 320T, a first source/drain region 314A and a second source/drain region 314B may be disposed. The first source/drain region 314A and the second source/drain region 314B may be disposed on both sides with the gate line trench 320T interposed therebetween. The first source/drain region 314A and the second source/drain region 314B may be regions doped with impurities of a different conductivity type from the impurities doped in the active pattern AC. For example, the first source/drain region 314A and the second source/drain region 314B may be doped with N-type or P-type impurities.

A gate structure 320 may be located inside the gate line trench 320T. The gate structure 320 may extend in a first direction (D1 direction) parallel to the upper surface of the substrate 310 and may be buried in the upper portion of the substrate 310. The gate structure 320 may include a gate insulating layer 322, a gate electrode 324, and a gate capping layer 326 sequentially formed on the inner wall surface of the gate line trench 320T.

The gate insulating layer 322 may be conformally formed on the inner wall surface of the gate line trench 320T. For example, the gate insulating layer 322 may be made of hafnium oxide (HfO₂), zirconium oxide (ZrO₂), aluminum oxide (Al₂O₃), hafnium-aluminum oxide (HfAlO₃), tantalum oxide (Ta₂O₃), titanium oxide (TiO₂), or a combination thereof. However, the material included in the gate insulating layer 322 is not limited thereto and may be variously changed.

The gate electrode 324 may be located on the gate insulating layer 322. The gate electrode 324 may extend from the bottom of the gate line trench 320T toward a third direction (D3 direction), which is a vertical direction, and may fill a portion of the gate line trench 320T. The gate electrode 324 may include a work function adjustment layer disposed on the gate insulating layer 322 and a buried metal layer filling the bottom of the gate line trench 320T on the work function adjustment layer. For example, the work function adjustment layer may include a metal, metal nitride, or metal carbide such as Ti, TiN, TiAlN, TiAlC, TiAlCN, TiSiCN, Ta, TaN, TaAlN, TaAlCN, TaSiCN, etc., and the buried metal layer may include at least one of W, WN, TiN, and TaN. However, the material included in the gate electrode 324 is not limited thereto and may be variously changed.

The gate capping layer 326 may be located on the gate electrode 324 and may fill the remaining region after the gate electrode 324 is formed in the gate line trench 320T. For example, the gate capping layer 326 may include at least one of silicon oxide, silicon oxynitride, and silicon nitride. However, the material included in the gate capping layer 326 is not limited thereto and may be variously changed.

A bit line structure 330 may be located on the first source/drain region 314A. The bit line structure 330 may be located on the central portion of the active pattern AC. The bit line structure 330 may be connected to the central portion of the active pattern AC.

The bit line structure 330 may include a bit line contact 332, a bit line 334, a bit line capping layer 336, and a bit line spacer 338 sequentially stacked on the substrate 310.

The bit line contact 332 may connect the bit line 334 and the first source/drain region 314A. The bit line contact 332 may be located between the bit line 334 and the first source/drain region 314A. The bit line contact 332 may be located at the overlapping portion of the bit line 334 and the first source/drain region 314A in a plan view. In FIG. 9, the bit line contact 332 is shown as a circle in a plan view, but it is not limited thereto, and the planar shape of the bit line contact 332 may be variously changed. The bit line contact 332 and the bit line 334 may include a conductive material. For example, the bit line contact 332 may include polysilicon, and the bit line 334 may include a metal material. However, the materials included in the bit line contact 332 and the bit line 334 are not limited thereto and may be variously changed.

In FIG. 10, the bit line contact 332 is shown as being formed to have a bottom surface at the same level as the upper surface of the substrate 310, but unlike this, a recess may be formed to a predetermined depth from the upper surface of the substrate 310 and the bit line contact 332 may extend into the recess, so that the bottom surface of the bit line contact 332 may be formed at a lower level than the upper surface of the substrate 310.

The bit line capping layer 336 may be located on the bit line 334. The bit line capping layer 336 may cover the upper surface of the bit line 334. The bit line capping layer 336 may include an insulating material such as silicon nitride or silicon oxynitride. However, the material included in the bit line capping layer 336 is not limited thereto and may be variously changed.

The bit line spacer 338 may cover the side surface of the bit line contact 332, the side surface of the bit line 334, and the side surface of the bit line capping layer 336, and may extend in a third direction (D3 direction) perpendicular to the substrate 310. The upper surface of the bit line spacer 338 may include a curved surface. The lower surface of the bit line spacer 338 may be in contact with the first source/drain region 314A and the gate insulating layer 322. In FIG. 10, the bit line spacer 338 is shown as being composed of a single layer, but it is not limited thereto, and in some embodiments, the bit line spacer 338 may be composed of a multi-layer including a plurality of insulating layers. The bit line spacer 338 may include an insulating material such as silicon oxide (SiO), silicon oxynitride (SiON), silicon nitride (SiN), or a combination thereof. However, the material included in the bit line spacer 338 is not limited thereto and may be variously changed.

A first insulating layer 342 and a second insulating layer 344 may be sequentially stacked on the substrate 310, and the bit line structure 330 may penetrate the first insulating layer 342 and the second insulating layer 344 to be connected to the first source/drain region 314A.

A contact 350 may be located on the substrate 310. The contact 350 may be located on the second source/drain region 314B. The contact 350 may electrically connect the second source/drain region 314B and a landing pad 352. The contact 350 may be located on an end portion of the active pattern AC. The contact 350 may be connected to the end portion of the active pattern AC. Here, the end portion of the active pattern AC may be located on both sides with respect to the central portion of the active pattern AC along the major axis direction of the active pattern AC. The side surface of the contact 350 may be surrounded by the first insulating layer 342 and the second insulating layer 344. The side surface of the contact 350 may be in contact with the first insulating layer 342 and the second insulating layer 344.

A third insulating layer 346 may be located on the second insulating layer 344. A landing pad 352 penetrating the third insulating layer 346 may be located on the contact 350. The landing pad 352 may electrically connect the contact 350 and the capacitor CAP.

The landing pad 352 may overlap with the entire upper surface of the contact 350 in a third direction (D3 direction) and may have a larger width than the contact 350. Accordingly, the landing pad 352 may be in contact with the contact 350 and the second insulating layer 344. The landing pad 352 may include at least one of a metal such as ruthenium (Ru), titanium (Ti), tantalum (Ta), niobium (Nb), iridium (Ir), molybdenum (Mo), tungsten (W), and a conductive metal nitride such as titanium nitride (TiN), tantalum nitride (TaN), niobium nitride (NbN), molybdenum nitride (MoN), tungsten nitride (WN). In addition, the landing pad 352 may include titanium nitride (TiN). However, the material included in the landing pad 352 is not limited thereto and may be variously changed.

The capacitor CAP may include a lower electrode 110, an upper electrode 120, a dielectric layer 130, a first metal oxide region 134, a second metal oxide region 136, a lower interface film 140, an upper interface film 150, and a supporter SPT. The descriptions for each of the lower electrode 110, the upper electrode 120, the dielectric layer 130, the first metal oxide region 134, the second metal oxide region 136, the lower interface film 140, and the upper interface film 150 may be the same as the descriptions in FIG. 1, so a duplicate description is omitted.

The supporter SPT may surround the lower electrode 110 and may be located on the side surface of the lower electrode 110. In FIG. 10, the number of supporters SPT located on the side surface of the lower electrode 110 is shown as one, but the number and arrangement of the supporters SPT are not limited thereto, and they may be omitted. In other words, one or more supporters SPT located spaced apart in the third direction (D3 direction) may be additionally disposed.

The supporter SPT may be disposed between the lower electrode 110 and another adjacent lower electrode 110. The lower electrode 110 may have a narrow width and a thick shape, and may fall or collapse due to this shape. The supporter SPT may function as a support member that prevents the lower electrode 110 from falling or collapsing. The supporter SPT may include silicon nitride (SiN), silicon oxynitride (SiON), silicon boron nitride (SiBN), or silicon carbonitride (SiCN). However, it is not limited thereto, and the material included in the supporter SPT may be variously changed.

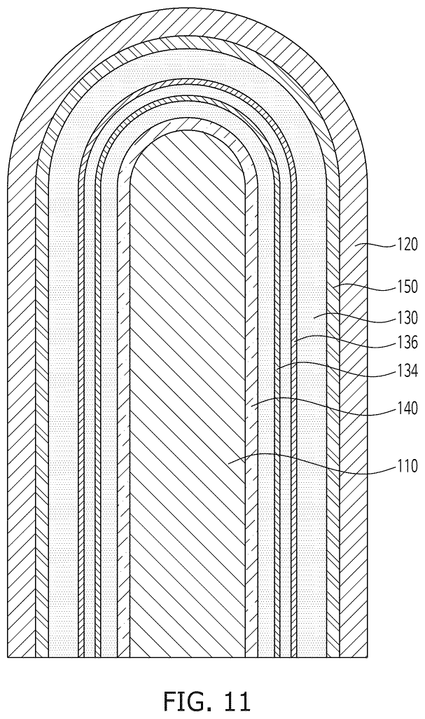

FIG. 11 is a diagram for explaining a capacitor according to some embodiments of the present disclosure. FIG. 11 is an enlarged view of the capacitor CAP of FIG. 10, and configurations that overlap with already described configurations may be omitted or simplified.

Referring to FIG. 11, a capacitor according to some embodiments may have a pillar shape. The capacitor having a pillar shape may include a lower electrode 110 having a pillar shape, a lower interface film 140 located on the lower electrode 110, a dielectric layer 130 located on the lower interface film 140, an upper interface film 150 located on the dielectric layer 130, and an upper electrode 120 located on the upper interface film 150.

The lower electrode 110 may have a pillar shape such as a cylinder, a square pillar, or the like. The lower interface film 140 may be located between the lower electrode 110 and the upper electrode 120 and may conformally cover the lower electrode 110. The dielectric layer 130 may be located between the lower electrode 110 and the upper electrode 120 and may conformally cover the lower interface film 140. The dielectric layer 130 may include a first metal oxide region 134 and a second metal oxide region 136 disposed to be spaced apart from the first metal oxide region 134. The first metal oxide region 134 and the second metal oxide region 136 may be conformally disposed within the dielectric layer 130. The upper interface film 150 may be located between the lower electrode 110 and the upper electrode 120 and may conformally cover the dielectric layer 130. The upper electrode 120 may be located on the upper interface film 150 and may conformally cover the upper interface film 150, but is not limited thereto.

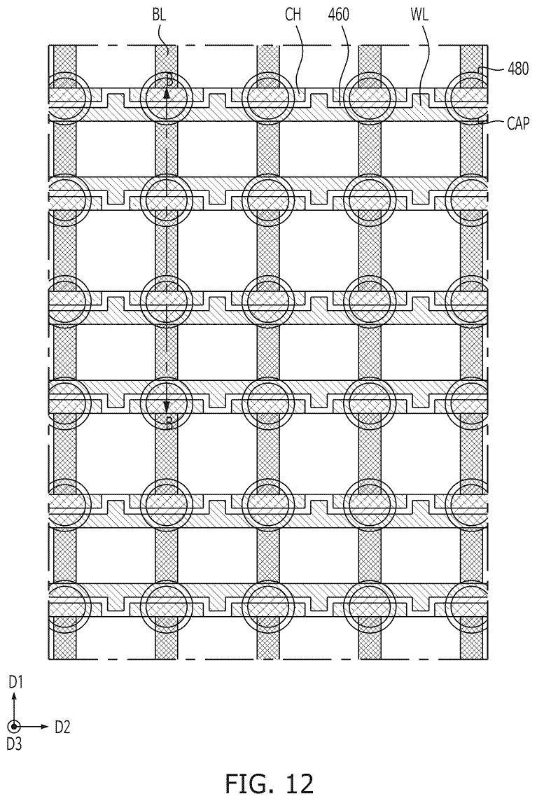

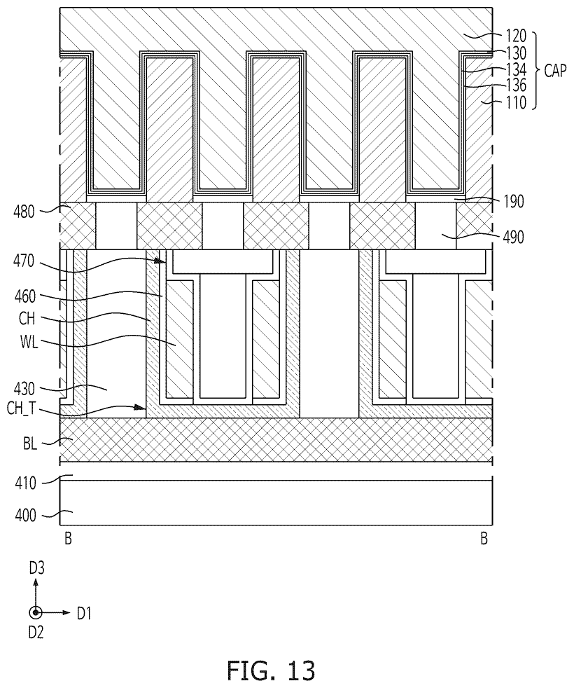

FIG. 12 is a diagram for explaining a semiconductor device according to some embodiments of the present disclosure. FIG. 13 is a cross-sectional view taken along line B-B of FIG. 12. Configurations that overlap with the above-described configurations may be omitted or simplified.

A semiconductor device according to some embodiments of the present disclosure may include memory cells including a vertical channel transistor (VCT). The vertical channel transistor may refer to a transistor in which the channel length extends in a direction perpendicular to the upper surface of the semiconductor substrate.

Referring to FIG. 12 and FIG. 13, a semiconductor device according to some embodiments may include a substrate 400, a wiring insulating film 410, a bit line BL, a channel structure CH, a word line WL, a mold pattern 430, a gate insulating film 460, a gate separation structure 470, a landing pad 480, an interlayer insulating film 490, and a capacitor CAP.

A plurality of transistors connected to the bit line BL may be disposed in the substrate 400. For example, a sensing transistor, a transfer transistor, a driving transistor, etc., may be disposed in the substrate 400. The type of transistor may vary depending on the design layout of the semiconductor memory device. The region where a plurality of transistors are disposed in the substrate 400 may be referred to as a peripheral circuit region.

The wiring insulating film 410 may be disposed on the substrate 400. In some embodiments, a wiring structure may be disposed in the wiring insulating film 410. The wiring structure may electrically connect the substrate 400 and the bit line BL. For example, a plurality of transistors disposed in the substrate 400 may be electrically connected to the bit line BL through the wiring structure.

The bit line BL may be disposed on the wiring insulating film 410. The bit line BL may extend in a first direction D1 on the wiring insulating film 410. Among a plurality of bit lines BL, adjacent bit lines BL may be disposed spaced apart from each other in a second direction D2. Here, the second direction D2 may be a direction perpendicular to the first direction D1.

The bit line BL may, for example, include at least one of doped polysilicon, a metal (for example, Al, Cu, Ti, Ta, Ru, W, Mo, Pt, Ni, Co), a conductive metal nitride (for example, TiN, TaN, WN, NbN, TiAlN, TiSiN, TaSiN, RuTiN), a conductive metal silicide, or a conductive metal oxide (for example, PtO, RuO₂, IrO₂, SRO(SrRuO₃), BSRO((Ba, Sr)RuO₃), CRO(CaRuO₃), LSCo), but the present disclosure is not limited thereto.

The mold pattern 430 may be disposed on the upper surface of the bit line BL. The mold pattern 430 may extend in the second direction D2. The mold patterns 430 may be spaced apart and aligned in the first direction D1.

The mold pattern 430 may include an insulating material. The mold pattern 430 may, for example, include at least one of silicon oxide, silicon nitride, silicon oxynitride, and a low-dielectric constant insulating material.

A channel trench CH_T may be disposed on the upper surface of the bit line BL. The bottom surface of the channel trench CH_T may be defined as the upper surface of the bit line BL. Both side surfaces of the channel trench CH_T may be defined by the side surfaces of the mold pattern 430 facing each other in the first direction D1. The channel trench CH_T may extend in the second direction D2. The channel trenches CH_T may be spaced apart in the first direction D1 and the second direction D2. The channel trench CH_T may expose the upper surface of the bit line BL.

The channel structure CH may be disposed on the upper surface of the bit line BL. The channel structure CH may be connected to the bit line BL. The channel structures CH disposed on one bit line BL may be spaced apart in the first direction D1.

The channel structure CH may be disposed within the channel trench CH_T. The channel structure CH may extend along the side and bottom surfaces of the channel trench CH_T. From a cross-sectional perspective, the channel structure CH may have an approximately “U” shape.

The word line WL may be disposed on the channel structure CH. The word line WL may intersect with the bit line BL. The word line WL may extend in the second direction D2. The word line WL may, for example, include at least one of doped polysilicon, a metal (for example, Al, Cu, Ti, Ta, Ru, W, Mo, Pt, Ni, Co), a conductive metal nitride (for example, TiN, TaN, WN, NbN, TiAlN, TiSiN, TaSiN, RuTiN), a conductive metal silicide, or a conductive metal oxide (for example, PtO, RuO₂, IrO₂, SRO(SrRuO₃), BSRO((Ba,Sr)RuO₃), CRO(CaRuO₃), LSCo), but the present disclosure is not limited thereto. The word line WL may include a single layer of each of the aforementioned materials or a multi-layer of those materials.

The gate insulating film 460 may be disposed between the word line WL and the channel structure CH. The gate insulating film 460 may include at least one of silicon oxide, silicon oxynitride, and a high-k material having a higher dielectric constant than silicon oxide. The high-k material may include a metal oxide or a metal oxynitride. For example, a high-k material usable as the gate insulating film 460 may include at least one of HfO₂, HfSiO, HfSiON, HfTaO, HfTiO, HfZrO, ZrO₂, and Al2O3, but the present disclosure is not limited thereto.

The gate separation structure 470 may be disposed on the bit line BL. The gate separation structure 470 may be disposed within the channel trench CH_T. The gate separation structure 470 may be disposed on the channel structure CH. In a semiconductor memory device according to some embodiments, the gate separation structure 470 may be in contact with the channel structure CH. The gate separation structure 470 may be in contact with a horizontal portion of the channel structure CH that extends in a direction parallel to the bit line BL. The gate separation structure 470 may be spaced apart from the bit line BL in a third direction D3.

The landing pad 480 may be disposed on the channel structure CH. The landing pad 480 may be in contact with the channel structure CH. The landing pad 480 may be electrically connected to the channel structure CH.

The landing pad 480 may be disposed on the gate separation structure 470 and the channel structure CH. From a planar perspective, the landing pad 480 may have various shapes such as a circle, an ellipse, a rectangle, a square, a rhombus, a hexagon, etc. From a planar perspective, the landing pads 480 may be arranged in various forms such as a matrix form, a zigzag form, a honeycomb form, etc., along the first direction D1 and the second direction D2. The landing pad 480 may be made of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but the present disclosure is not limited thereto.

The interlayer insulating film 490 may be disposed on the mold pattern 430 and the gate separation structure 470. The interlayer insulating film 490 may include an insulating material.

An etch stop film 190 may be disposed on the landing pad 480 and the interlayer insulating film 490. The etch stop film 190 may expose the landing pad 480.

The capacitor CAP may be disposed on the landing pad 480 and the interlayer insulating film 490. The capacitor CAP may store signals transmitted from transistors in the peripheral circuit structure (for example, row and column decoders, sense amplifiers, etc.) of the semiconductor memory device. The capacitor CAP may be used as an information storage element electrically connected to a transistor. For example, the capacitor CAP may store charge under the control of a transistor.

The capacitor CAP may include a lower electrode 110, an upper electrode 120, a dielectric layer 130, a first metal oxide region 134, a second metal oxide region 136, a lower interface film 140, and an upper interface film 150. The descriptions for each of the lower electrode 110, the upper electrode 120, the dielectric layer 130, the first metal oxide region 134, the second metal oxide region 136, the lower interface film 140, and the upper interface film 150 may be the same as the descriptions in FIG. 1, so a duplicate description is omitted.

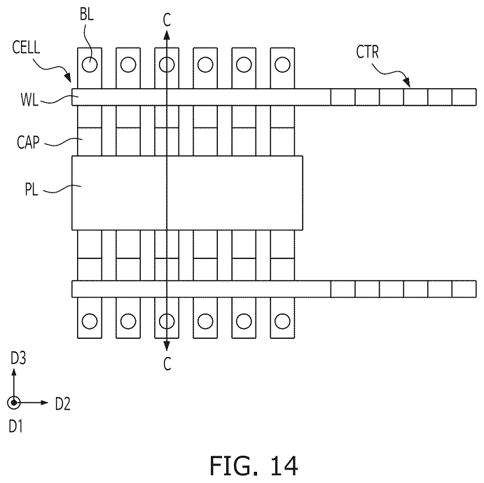

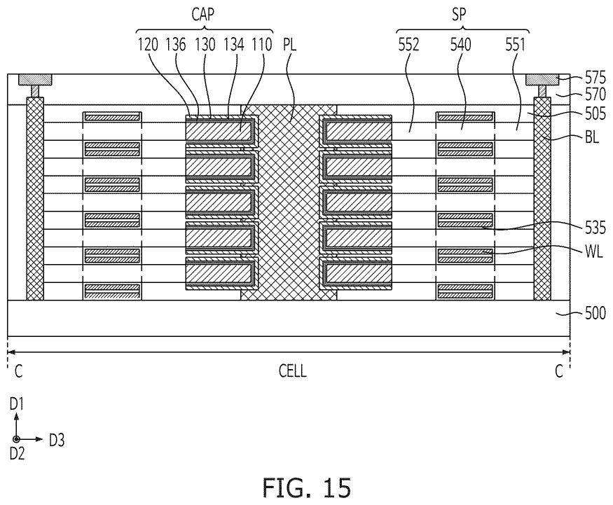

FIG. 14 is a diagram for explaining a semiconductor device according to some embodiments of the present disclosure. FIG. 15 is a cross-sectional view taken along line C-C of FIG. 14. Configurations that overlap with the above-described configurations may be omitted or simplified.

Referring to FIG. 14 and FIG. 15, a semiconductor device according to some embodiments may be a memory device including a stacked channel. The semiconductor device may include a substrate 500, a cell insulating film 505, a gate insulating film 535, a capacitor CAP, a cell semiconductor pattern SP, a word line WL, a plate electrode PL, and a bit line BL.

The substrate 500 may include a cell area CELL and a contact area CTR. The cell semiconductor pattern SP may be disposed on the cell area CELL of the substrate 500. A plurality of cell semiconductor patterns SP and a plurality of cell insulating films 505 may be alternately stacked on the upper surface of the substrate 500. The cell semiconductor pattern SP may have a line shape, a bar shape, or a pillar shape extending in a second direction D2. The cell semiconductor pattern SP may penetrate the word line WL.

The cell semiconductor pattern SP may include a cell channel pattern 540, a first source/drain pattern 551, and a second source/drain pattern 552.

The cell channel pattern 540 may be disposed between the first source/drain pattern 551 and the second source/drain pattern 552. The cell channel pattern 540 may be disposed between the word lines WL. In some embodiments, the word line WL may have a structure that surrounds the cell channel pattern 540 (i.e., a gate all around structure).

The first source/drain pattern 551 may be disposed at one end of the cell channel pattern 540. The first source/drain pattern 551 may be connected to the bit line BL. The second source/drain pattern 552 may be disposed at the other end of the cell channel pattern 540. The second source/drain pattern 552 may be connected to the capacitor CAP.

The first source/drain pattern 551 and the second source/drain pattern 552 may have a first conductivity type (for example, n-type). The cell channel pattern 540 may be undoped or have a second conductivity type (for example, p-type) different from the first conductivity type.

Each of the plurality of word lines WL may extend in a first direction D1 parallel to the upper surface of the substrate 500. Each of the plurality of word lines WL may surround the cell channel pattern 540. The plurality of word lines WL may be disposed in the cell area CELL and the contact area CTR. The plurality of word lines WL may have a stepped shape on the contact area CTR. Each of the plurality of word lines WL may include a pad portion where a part of the upper surface is exposed due to the stepped shape. A contact via may be connected on the pad portion of the word line WL.

The word line WL may include a conductive material. The word line WL may, for example, include at least one of a doped semiconductor material, a conductive metal nitride, and a metal-semiconductor compound, but the present disclosure is not limited thereto.

The gate insulating film 535 may be disposed between the cell channel pattern 540 and the word line WL. The gate insulating film 535 may surround the cell channel pattern 540. The word line WL may be disposed on the gate insulating film 535. The gate insulating film 535 may include at least one of a high-k insulating film, a silicon oxide film, a silicon nitride film, and a silicon oxynitride film.

The cell insulating film 505 may be disposed between the cell semiconductor patterns SP stacked in a third direction D3. A part of the cell insulating film 505 may be disposed between adjacent word lines WL in the third direction D3. The cell insulating film 505 may electrically separate the word lines WL. The cell insulating film 505 may include an insulating material.

The capacitor CAP may include a lower electrode 110, an upper electrode 120, a dielectric layer 130, a first metal oxide region 134, a second metal oxide region 136, a lower interface film, and an upper interface film. The lower electrode 110 may be disposed at one end of the cell semiconductor pattern SP. The lower electrode 110 may be connected to the second source/drain pattern 552. The lower electrode 110 may have a pillar shape extending in the second direction D2.

The dielectric layer 130 may be disposed between the lower electrode 110 and the upper electrode 120. The dielectric layer 130 may be disposed along the profile of the lower electrode 110.

The upper electrode 120 may be disposed on the dielectric layer 130. The upper electrode 120 may extend along the dielectric layer 130. The upper electrode 120 may be connected to the plate electrode PL.

The descriptions for each of the dielectric layer 130, the first metal oxide region 134, the second metal oxide region 136, the lower interface film 140, and the upper interface film 150 may be the same as the descriptions in FIG. 1, so a duplicate description is omitted.

The plate electrode PL may extend in a first direction D1 and a third direction D3. The plate electrode PL may be in contact with the upper electrode 120. The plate electrode PL may be electrically connected to a plurality of upper electrodes 120 disposed in the first direction D1. The plate electrode PL may include a conductive material. The plate electrode PL may, for example, include one of a doped semiconductor material, a conductive metal nitride, a metal, and a metal-semiconductor compound.

The bit line BL may be disposed on the substrate 500. The bit line BL may extend in a third direction D3. For example, the bit line BL may penetrate a plurality of stacked cell semiconductor patterns SP. The cell semiconductor patterns SP may be connected to the bit line BL. For example, the bit line BL may be electrically connected to the first source/drain pattern 551 of the cell semiconductor pattern SP.

A cell interlayer insulating film 570 may cover the bit line, the cell insulating film 505, and the plate electrode PL. A wiring structure 575 may be disposed on the bit line BL. The wiring structure 575 may be disposed in the cell interlayer insulating film 570 and may be electrically connected to the bit line BL.

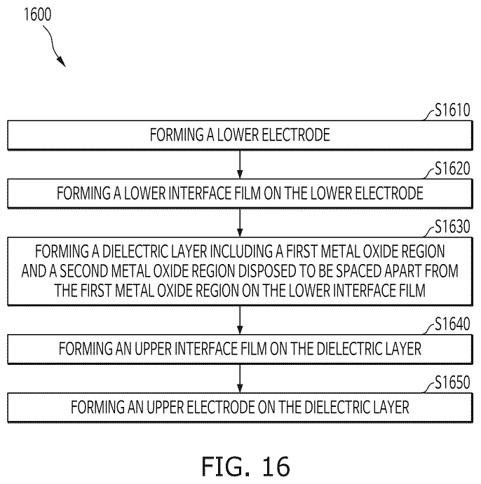

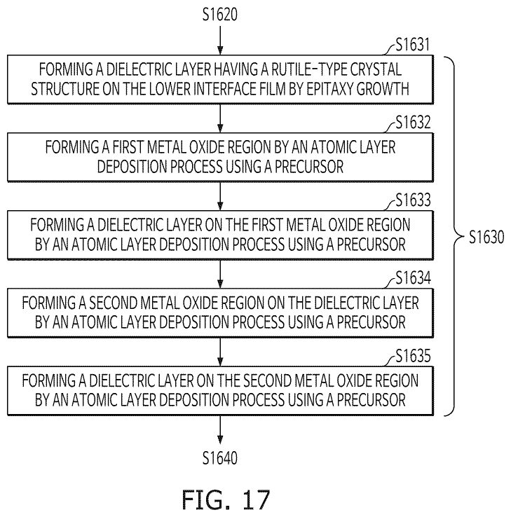

FIG. 16 and FIG. 17 are flowcharts illustrating a method of manufacturing a capacitor according to some embodiments of the present disclosure.

Referring to FIG. 16 and FIG. 17, a method 1600 of manufacturing a capacitor according to some embodiments of the present disclosure may include a step S1610 of forming a lower electrode, a step S1620 of forming a lower interface film on the lower electrode, a step S1630 of forming a dielectric layer including a first metal oxide region and a second metal oxide region disposed to be spaced apart from the first metal oxide region on the lower interface film, a step S1640 of forming an upper interface film on the dielectric layer, and a step S1650 of forming an upper electrode on the upper interface film.

In the method 1600 of manufacturing a capacitor, the third step S1630 of forming the dielectric layer including the first metal oxide region and the second metal oxide region disposed to be spaced apart from the first metal oxide region on the lower interface film may include a first sub-step S1631 of forming a dielectric layer having a rutile-type crystal structure by epitaxy growth on the lower interface film, a second sub-step S1632 of forming the first metal oxide region by an atomic layer deposition process using a precursor on the dielectric layer, a third sub-step S1633 of forming a dielectric layer by an atomic layer deposition process using a precursor on the first metal oxide region, a fourth sub-step S1634 of forming the second metal oxide region by an atomic layer deposition process using a precursor on the dielectric layer, and a fifth sub-step S1635 of forming a dielectric layer by an atomic layer deposition process using a precursor on the second metal oxide region.

In some embodiments, the second sub-step S1632 may be repeated X times, and the fourth sub-step S1634 may be repeated Y times. The number of repetitions (X, Y) for each of the second sub-step S1632 and the fourth sub-step S1634 may vary as needed. Accordingly, the thickness of each of the first metal oxide region and the second metal oxide region may vary.

First, a substrate may be provided into a chamber where a capacitor manufacturing process will be performed. The substrate may be, for example, a silicon semiconductor substrate, a compound semiconductor substrate, a glass substrate, a plastic substrate, or the like. However, the present disclosure is not limited thereto.

A lower electrode may be formed (S1610). The lower electrode may be disposed on a substrate. The substrate may be a part of a structure supporting the capacitor or a part of a device connected to the capacitor. The lower electrode may independently include a metal such as platinum (Pt), iridium (Ir), ruthenium (Ru), molybdenum (Mo), vanadium (V), etc., a conductive metal nitride such as titanium nitride (TiN), niobium nitride (NbN), titanium silicon nitride (TiSiN), molybdenum nitride (MoN), vanadium nitride (VN), scandium nitride (ScN) or any combination thereof, and/or a conductive metal oxide such as platinum oxide (PtO), iridium oxide (IrO₂), ruthenium oxide (RuO₂), strontium ruthenium oxide (SrRuO₃), barium strontium ruthenium oxide ((Ba,Sr)RuO₃), calcium ruthenium oxide (CaRuO₃), lanthanum strontium cobalt oxide ((La, Sr)CoO₃).

Next, a lower interface film may be formed on the lower electrode (S1620). The lower interface film may include a transition metal oxide having electrical conductivity. Specifically, the lower interface film may include an oxide of a metal included in the lower electrode. For example, the lower interface film may include TiO₂, Nb₂O₃, MoO₂, RuO₂, IrO₂, VO₂, Sc₂O₃, Ta₂O₅, SnO₂, or any combination thereof.

Next, a dielectric layer including a first metal oxide region and a second metal oxide region disposed to be spaced apart from the first metal oxide region may be formed on the lower interface film (S1630). The process of forming the dielectric layer may be performed under a temperature condition of 200° C.-400° C. For example, the process of forming the dielectric layer may be performed under a temperature condition of about 300° C.

In some embodiments, first, as a first sub-step S1631, a dielectric layer having a rutile-type crystal structure may be formed on the lower interface film by epitaxy growth. At least a part of the dielectric layer may be an epitaxial layer. The dielectric layer may be formed by, for example, epitaxy growth. Accordingly, the dielectric layer may have the same or similar crystal structure, the same or similar lattice constant, etc. as the lower electrode or the lower interface film. A part or all of the dielectric layer may include an epitaxial region. The dielectric layer may have a rutile-type crystal structure. For example, the dielectric layer may include TiO2 in a rutile phase.

Atomic layer deposition (ALD) may supply the source gases for film formation not simultaneously but in a time-divided manner in the form of independent pulses. Such ALD may interpose a purge step with an inert gas between the supplies of the source gases to remove remaining gases or by-products that have not reacted (or chemically adsorbed). For the purge step, an inert gas such as Ar, He, Ne and/or N₂ gas may be used.

For example, when a precursor is supplied to a reactor and then the reactor is purged by supplying an inert gas (purge gas), a thin layer of the chemically adsorbed precursor may remain on the substrate surface at a monolayer level, and all the remaining precursor may exit the reactor. Thereafter, when an oxidant is supplied, it may react with the precursor on the substrate surface to form a desired dielectric layer thinly (for example, as a monolayer). Thereafter, a purge step may be performed to remove the physically adsorbed oxidant or by-products in the reactor. The process consisting of precursor supply→purge→oxidant supply→purge is called one cycle of a general ALD process, and a film may be formed to a desired thickness by controlling the number of cycles. As the precursor for the dielectric layer, a Ti-containing precursor may be used. For example, the Ti-containing precursor may include a Ti-containing alkoxide (for example, Ti-tetra-isopropoxide (TTIP), Ti(CpMe₅) (OMe)₃ (pentamethyl cyclopentadienyl titanium trimethoxide), etc.), a Ti-containing amine (for example, TDMAT(tetra-kis(dimethylamino)titanium), etc.), a Ti-containing halide (for example, TiCl₄, TiI₄, etc.), or a combination thereof. As the oxidant, O₃, N₂O and/or plasma may be used. The precursor for the dielectric layer may be supplied for 3 seconds, and then a purge gas may be injected for 10 seconds. Thereafter, the oxidant may be supplied for 10 seconds, and then a purge gas may be injected.

Subsequently, as a second sub-step S1632, the first metal oxide region may be formed by an atomic layer deposition process using a precursor. The first metal oxide region may include an oxide of a tetravalent metal. Specifically, the first metal oxide region may include lead oxide (PbO₂), tin oxide (SnO₂), germanium oxide (GeO₂), or any combination thereof. The first metal oxide region may be deposited by a general ALD process, which is a process consisting of precursor supply→purge→oxidant supply→purge, or an ACALD(Atomic Layer Co-Deposition) process, which is a process consisting of first precursor supply→purge→second precursor supply→purge→oxidant supply→purge. In the general ALD process, a Ge-containing precursor may be used as the precursor for the first metal oxide region. In the ACALD process, a Ti-containing precursor may be used as the first precursor. In the ACALD process, a Ge-containing precursor may be used as the second precursor. For example, the Ge-containing precursor may include Ge(OnBu)₄, Ge(NMe₂)₄, GeCl₄, or any combination thereof. In the case of the general ALD process, the precursor for the first metal oxide region may be supplied for 5 seconds, and then a purge gas may be injected for 10 seconds. Thereafter, the oxidant may be supplied for 10 seconds, and then a purge gas may be injected. In the case of the ACALD process, the first precursor may be supplied for 3 seconds, then a purge gas may be injected for 10 seconds, and the second precursor may be supplied for 5 seconds, then a purge gas may be injected for 10 seconds. Thereafter, the oxidant may be supplied for 10 seconds, and then a purge gas may be injected. The number of cycles for forming the first metal oxide region may be 10-15.

When the first metal oxide region is formed by a general ALD process, the first metal oxide region may be a layer-shaped region formed within the dielectric layer. When the first metal oxide region is formed by an ACALD process, the first metal oxide region may be a region where an oxide of a tetravalent metal is distributed in a doped form within the dielectric layer.

Next, as a third sub-step S1633, a dielectric layer may be formed on the first metal oxide region by an atomic layer deposition process using a precursor. It may be deposited by a general ALD process, which is a process consisting of precursor supply→purge→oxidant supply→purge. As the precursor for the dielectric layer, a Ti-containing precursor may be used. The precursor for the dielectric layer may be supplied for 3 seconds, and then a purge gas may be injected for 10 seconds. Thereafter, the oxidant may be supplied for 10 seconds, and then a purge gas may be injected.

Next, as a fourth sub-step S1634, the second metal oxide region may be formed on the dielectric layer by an atomic layer deposition process using a precursor. The second metal oxide region may include BaO, SrO, CaO, MgO, ZnO, CdO, BeO, or any combination thereof. The second metal oxide region may be deposited by a general ALD process, which is a process consisting of precursor supply→purge→oxidant supply→purge, or an ACALD process, which is a process consisting of first precursor supply→purge→second precursor supply→purge→oxidant supply→purge. In the general ALD process, an Mg-containing precursor may be used as the precursor for the second metal oxide region. In the ACALD process, a Ti-containing precursor may be used as the first precursor. In the ACALD process, an Mg-containing precursor may be used as the second precursor. For example, the Mg-containing precursor may include MgCp₂ (Mg(C₅H₅)₂), Mg(EtCp)₂ (Mg(C₅H₄C₂H₅)₂), or any combination thereof. In the case of the general ALD process, the precursor for the second metal oxide region may be supplied for 3 seconds, and then a purge gas may be injected for 20 seconds. Thereafter, the oxidant may be supplied for 10 seconds, and then a purge gas may be injected. In the case of the ACALD process, the first precursor may be supplied for 3 seconds, then a purge gas may be injected for 10 seconds, and the second precursor may be supplied for 3 seconds, then a purge gas may be injected for 20 seconds. Thereafter, the oxidant may be supplied for 10 seconds, and then a purge gas may be injected.

When the second metal oxide region is formed by a general ALD process, the second metal oxide region may be a layer-shaped region formed within the dielectric layer. When the second metal oxide region is formed by an ACALD process, the second metal oxide region may be a region where an oxide of a divalent metal is distributed in a doped form within the dielectric layer. The second metal oxide region may be formed in a doped form within the crystal lattice of the dielectric layer. Specifically, the second metal oxide region may have the form of ion substitution at the metal ion sites constituting the dielectric layer and may be formed dispersed within the dielectric layer.

Next, as a fifth sub-step S1635, a dielectric layer may be formed on the second metal oxide region by an atomic layer deposition process using a precursor. It may be deposited by a general ALD process, which is a process consisting of precursor supply→purge→oxidant supply→purge. As the precursor for the dielectric layer, a Ti-containing precursor may be used. The precursor for the dielectric layer may be supplied for 3 seconds, and then a purge gas may be injected for 10 seconds. Thereafter, the oxidant may be supplied for 10 seconds, and then a purge gas may be injected. The number of cycles for forming the second metal oxide region may be 1-9. The total number of cycles of the steps for forming the dielectric layer (S1631, S1633, S1635) may be about 150-250.

Next, an upper interface film may be formed on the dielectric layer (S1640). The upper interface film may include a transition metal oxide having electrical conductivity. Specifically, the upper interface film may include an oxide of a metal included in the upper electrode. For example, the upper interface film may include TiO₂, Nb₂O₃, MoO₂, RuO₂, IrO₂, VO₂, Sc₂O₃, Ta₂O₅, SnO₂, or any combination thereof.

Finally, an upper electrode may be formed on the dielectric layer (S1650). The upper electrode may be disposed to be spaced apart from and face the lower electrode. The upper electrode may independently include a metal, a metal nitride, a metal oxide, or a combination thereof. Specifically, the upper electrode may each independently include a metal such as platinum (Pt), iridium (Ir), ruthenium (Ru), molybdenum (Mo), vanadium (V), etc., a conductive metal nitride such as titanium nitride (TiN), niobium nitride (NbN), titanium silicon nitride (TiSiN), molybdenum nitride (MoN), vanadium nitride (VN), scandium nitride (ScN) or any combination thereof, and/or a conductive metal oxide such as platinum oxide (PtO), iridium oxide (IrO₂), ruthenium oxide (RuO₂), strontium ruthenium oxide (SrRuO₃), barium strontium ruthenium oxide ((Ba,Sr)RuO₃), calcium ruthenium oxide (CaRuO₃), lanthanum strontium cobalt oxide ((La,Sr)CoO₃).

While the present disclosure has been described with reference to the limited embodiments and drawings, the present disclosure is not limited thereto, and it is apparent that various modifications and variations can be made by those skilled in the art to which the present disclosure pertains without departing from the technical spirit of the present disclosure and the equivalent scope of the claims to be described below.

What is claimed is:

1. A capacitor, comprising:
a lower electrode;
an upper electrode disposed to be spaced apart from the lower electrode; and
a dielectric layer disposed between the lower electrode and the upper electrode,
wherein:
the dielectric layer comprises a first metal oxide region and a second metal oxide region disposed to be spaced apart from the first metal oxide region,
the first metal oxide region comprises an oxide of a tetravalent metal, and
the second metal oxide region comprises an oxide of a divalent metal.

2. The capacitor of claim 1, wherein the first metal oxide region comprises PbO₂, SnO₂, GeO₂, or any combination thereof.

3. The capacitor of claim 2, wherein the first metal oxide region has a Rutile phase crystal structure.

4. The capacitor of claim 1, wherein the second metal oxide region comprises BaO, SrO, CaO, MgO, ZnO, CdO, BeO, or any combination thereof.

5. The capacitor of claim 1, wherein:
the first metal oxide region is a region where the oxide of the tetravalent metal is distributed in a doped form within the dielectric layer, and
the second metal oxide region is a region where the oxide of the divalent metal is distributed in a doped form within the dielectric layer.

6. The capacitor of claim 1, wherein each of the first metal oxide region and the second metal oxide region is a layer-shaped region formed within the dielectric layer.

7. The capacitor of claim 1, wherein the first metal oxide region is located closer to the lower electrode than the second metal oxide region.

8. The capacitor of claim 7, wherein:
when measured from the lower electrode, the first metal oxide region is located in a region between 10% and 40% of a thickness of the dielectric layer, and
when measured from the lower electrode, the second metal oxide region is located in a region between 40% and 100% of the thickness of the dielectric layer.

9. The capacitor of claim 1, wherein the first metal oxide region is located farther from the lower electrode than the second metal oxide region.

10. The capacitor of claim 1, wherein a thickness of the first metal oxide region is greater than a thickness of the second metal oxide region.

11. The capacitor of claim 1, further comprising a lower interface film disposed between the lower electrode and the dielectric layer.

12. The capacitor of claim 11, wherein the lower interface film comprises TiO₂, Nb₂O₃, MoO₂, RuO₂, IrO₂, VO₂, Sc₂O₃, Ta₂O₅, SnO₂, or any combination thereof.

13. The capacitor of claim 1, further comprising an upper interface film disposed between the upper electrode and the dielectric layer.

14. The capacitor of claim 13, wherein the upper interface film comprises TiO₂, Nb₂O₃, MoO₂, RuO₂, IrO₂, VO₂, Sc₂O₃, Ta₂O₅, SnO₂, or any combination thereof.

15. The capacitor of claim 1, wherein each of the lower electrode and the upper electrode comprises Pt, Ir, Ru, Mo, V, TiN, NbN, TiSiN, MoN, VN, ScN, or any combination thereof.

16. The capacitor of claim 1, wherein at least a portion of the dielectric layer is an epitaxial layer and has a rutile-type crystal structure.

17. The capacitor of claim 1, wherein the dielectric layer comprises ZrO₂, HfO₂, ZrHfO, TiO₂, Al₂O₃, GeO₂, Y₂O₃, MgO, Sc₂O₃, Ga₂O₃, In₂O₃, SiO₂, or any combination thereof.

18. A capacitor, comprising:
a lower electrode;
an upper electrode disposed to be spaced apart from the lower electrode;
a dielectric layer disposed between the lower electrode and the upper electrode;
a lower interface film disposed between the lower electrode and the dielectric layer; and
an upper interface film disposed between the upper electrode and the dielectric layer,
wherein:
the dielectric layer comprises a first metal oxide region and a second metal oxide region disposed to be spaced apart from the first metal oxide region,
each of the first metal oxide region and the second metal oxide region is a region distributed in a doped form within the dielectric layer or a layer-shaped region formed within the dielectric layer,
the first metal oxide region comprises PbO₂, SnO₂, GeO₂, or any combination thereof and has a rutile-type crystal structure,
the second metal oxide region comprises BaO, SrO, CaO, MgO, ZnO, CdO, BeO, or any combination thereof, and
the first metal oxide region is located closer to the lower electrode than the second metal oxide region.

19. A semiconductor device, comprising:
a transistor disposed on a substrate; and
a capacitor electrically connected to the transistor,
wherein the capacitor comprises:
a lower electrode;
an upper electrode disposed to be spaced apart from the lower electrode; and
a dielectric layer disposed between the lower electrode and the upper electrode,
wherein:
the dielectric layer comprises a first metal oxide region and a second metal oxide region disposed to be spaced apart from the first metal oxide region,
the first metal oxide region comprises an oxide of a tetravalent metal, and
the second metal oxide region comprises an oxide of a divalent metal.

20. The semiconductor device of claim 19, wherein the transistor comprises:
a semiconductor substrate including a source region, a drain region and a channel region located between the source region and the drain region; and
a gate structure disposed on the semiconductor substrate to face the channel region and comprising a gate insulating layer and a gate electrode.
